(19) United States
(12) Patent Application Publication
(10) Pub. No.: US 2018/0019283 A1
(43) Pub. Date: Jan. 18, 2018

(54) TANDEM ORGANIC-INORGANIC PHOTOVOLTAIC DEVICES

(71) Applicant: The Regents of the University of California, Oakland, CA (US)

(72) Inventors: Yang YANG, Los Angeles, CA (US); Ziruo HONG, Los Angeles, CA (US); Gang LI, Arcadia, CA (US)

(73) Assignee: The Regents of the University of California, Oakland, CA (US)

(21) Appl. No.: 15/546,154

(22) PCT Filed: Jan. 28, 2016
(86) PCT No.: PCT/US2016/015400

§ 371 Date: Jul. 25, 2017

Related U.S. Application Data
(60) Provisional application No. 62/108,943, filed on Jan. 28, 2015.

(51) Int. Cl. H01L 27/30; H01L 31/0376; H01L 51/42; H01L 27/28; H01L 31/0224; H01L 51/44; H01L 31/0256; H01L 51/00

(52) U.S. Cl. CPC H01L 27/302; H01L 31/022475; H01L 31/022483; H01L 31/03762; H01L 51/447; H01L 51/4253; H01L 51/442; H01L 27/286; H01L 51/0036; H01L 51/0037; H01L 51/0043; H01L 51/0046; H01L 2031/0344; H01L 51/004

(57) ABSTRACT

A tandem photovoltaic cell includes a substrate, a first electrode formed on the substrate, and a first sub-cell comprising a first light absorption material and formed on the first electrode. The tandem photovoltaic cell further includes an inter-cell layer formed on the first sub-cell, a second sub-cell comprising a second light absorption material and formed on the inter-cell layer, and a second electrode formed on the second sub-cell. The second electrode is at least partially transparent to light of a spectral range that can be absorbed by the first and second absorption materials. The inter-cell layer provides electrical connection between the first and second sub-cells and is at least partially transparent to light of at least a portion of the spectral range, and the second sub-cell has a refractive index to light within the spectral range that is less than a refractive index of the first sub-cell.

This application claims priority to U.S. Provisional Application No. 62/108,943 filed Jan. 28, 2015, the entire content of which is hereby incorporated by reference.

This invention was made with Government support under 1202231, awarded by the National Science Foundation. The Government has certain rights in the invention.

### BACKGROUND

### 1. Technical Field

Some embodiments of the present invention relate to tandem photovoltaic devices, and more particularly to tandem organic-inorganic photovoltaic devices.

### 2. Discussion of Related Art

Conjugated polymer and hydrogenated amorphous silicon (a-Si:H) have been considered excellent candidate materials for fabricating low-cost, lightweight, and flexible photovoltaic devices, since ultrathin absorbers (hundreds of nanometer scale) are capable of harvesting the most photons within the spectral range allowed by the band gap. [1-3] Both techniques feature relatively short energy-pay-back time, ranging from one to two years. [4] Polymer solar cells based on conjugated polymers as electron-donor materials blended with [6,6]-phenyl-C71-butyric acid methyl ester (PC71BM) as an electron-acceptor have achieved 7-9% power conversion efficiency using a single bulk heterojunction structure. [5-8] The efficiency of single junction a-Si:H solar cells is typically less than 10% even with a highly textured configuration. [2-3] These efficiencies of polymer and a-Si:H cells are not acceptable for achieving grid parity. There thus remains a need for solar cells having improved efficiency.

### SUMMARY

According to some embodiments of the invention, a tandem photovoltaic cell includes a substrate, a first electrode formed on the substrate, and a first sub-cell comprising a first light absorption material and formed on the first electrode. The tandem photovoltaic cell further includes an inter-cell layer formed on the first sub-cell, a second sub-cell comprising a second light absorption material and formed on the inter-cell layer, and a second electrode formed on the second sub-cell. The second electrode is at least partially transparent to light of a spectral range that can be absorbed by the first and second absorption materials, the second electrode being on a light reception side of the tandem photovoltaic cell. The inter-cell layer provides electrical connection between the first and second sub-cells and is at least partially transparent to light of at least a portion of the spectral range, and the second sub-cell has a refractive index to light within the spectral range that is less than a refractive index of the first sub-cell to light within the spectral range.

According to some embodiments of the invention, the second sub-cell is an organic sub-cell and the first sub-cell is an inorganic sub-cell. According to some embodiments, the second sub-cell is a multilayered sub-cell. According to some embodiments, the first sub-cell has a refractive index to light within the spectral range that is greater than 3.5.

According to some embodiments of the invention, a tandem photovoltaic cell includes a substrate, a first electrode formed on the substrate, a first sub-cell comprising a first light absorption material and formed on the first electrode, and an inter-cell layer formed on the first sub-cell. The tandem photovoltaic cell further includes a second sub-cell comprising a second light absorption material and formed on the inter-cell layer, and a second electrode formed on the second sub-cell. At least one of the first sub-cell, the second sub-cell, or the inter-cell layer has a surface that is rough on a scale of wavelengths of light that can pass therethrough.

According to some embodiments of the invention, the second sub-cell is an organic sub-cell and the first sub-cell is an inorganic sub-cell. According to some embodiments, the surface that is rough comprises substantially triangular structures. According to some embodiments, the substantially triangular structures have bases that are approximately 1500 nm to within about 10% and have sides that make an angle of about 30 degrees (to within a few degrees) with the base.

According to some embodiments of the invention, a tandem photovoltaic cell includes a substrate, a first electrode formed on the substrate, a first sub-cell comprising a first light absorption material and formed on the first electrode, and an inter-cell layer formed on the first sub-cell. The tandem photovoltaic cell further includes a second sub-cell comprising a second light absorption material and formed on the inter-cell layer, and a second electrode formed on the second sub-cell. The inter-cell layer provides electrical connection between the first and second sub-cells and is at least partially transparent to light of at least a portion of the spectral range, and the inter-cell layer comprises a p-type metal oxide.

According to some embodiments of the invention, the second sub-cell is an organic sub-cell and the first sub-cell is an inorganic sub-cell. According to some embodiments, the p-type metal comprises at least one of an oxide or sub-oxides of Mo, V, W, or Ni. According to some embodiments, the inter-cell layer further comprises a layer of ZnO:Al formed on the first sub-cell, wherein a layer comprising the p-type metal oxide is formed on the layer of ZnO:Al.

### BRIEF DESCRIPTION OF THE DRAWINGS

Further objectives and advantages will become apparent from a consideration of the description, drawings, and examples.

FIG. 1 illustrates tandem cell structure based on organic and inorganic sub-units in serial connection according to some embodiments of the invention;

FIG. 2 is a plot of efficiency vs film thickness of a-Si:H p-i-n single junction cells on flat and textured substrates;

FIG. 3 is a plot of efficiency vs film thickness of polymer single junction photovoltaic cells;

FIG. 4 shows current-voltage (J-V) characteristics of a a-Si:H/polymer hybrid tandem solar cell, together with single junction references;

FIG. 5 shows a schematic of a tandem solar cell, Tandem I, having a flat surface morphology and using ITO/PEDOT:PSS to connect the two sub-cells;

FIG. 6 shows a schematic of two tandem solar cells, Tandem II and Tandem III, having a textured morphology and using ITO/PEDOT:PSS to connect the two sub-cells;

FIG. 7 shows a schematic of a tandem solar cell, Tandem IV, having a flat surface morphology and using ZnO:Al/MoO₃ to connect the two sub-cells;

FIG. 8 shows a typical cross-sectional SEM image of a tandem cell made on a flat surface such as Tandem I and Tandem IV;

FIG. 9 shows a typical cross-sectional SEM image of a tandem cell made on a textured surface such as Tandem II and III;

FIG. 10 provides external quantum efficiency (EQE) curves of sub-cells in Tandem I, and respective single junction reference cells;

FIG. 11 illustrates J-V characteristics of tandem I, II and III;

FIG. 12 shows EQE of sub-cells in Tandem IV, and respective single junction reference cells;

FIG. 13 shows J-V characteristics of Tandem I and IV;

FIG. 14 shows the absorbed photon flux as a function of thickness for the a-Si p-i-n sub-cells incorporating MoO3 and PEDOT in the interconnection layers, respectively;

FIG. 15 show the absorbed photon flux as a function of thickness for the polymer:fullerene bulk heterojunctions sub-cell incorporating MoO3 and PEDOT in the interconnection layers, respectively;

FIG. 16 plots the EQE of the front a-Si sub-cell with different topping layers;

FIG. 17 shows the optical field distribution of near IR light at 850 nm in a polymer back sub-cell;

FIG. 18 shows the optical field distribution of visible light at 500 nm in an a-Si front sub-cell;

FIG. 19 shows J-V characteristics of polymer single junction references cells using MoO3 and PEDOT as an anode buffer; and

FIG. 20 shows the EQE of polymer single junction references cells using MoO3 and PEDOT as an anode buffer.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

There is a need for improvement of the efficiency of organic and inorganic thin film photovoltaic cells. Considering the trade-off between sufficient light absorption and limited carrier diffusion length, the thickness and thus absorbance of the photoactive layers is one of the limiting factors for efficiency. Therefore it is useful to employ a tandem structure, that is, stacking multiple PV materials (hence junctions), for better light harvesting.

Unlike organic films, inorganic materials for photovoltaics usually have high refractive indices larger than 3.5, resulting in significant optical loss of up to 40% at the air (or glass)/inorganic interfaces due to the reflection of incident light. According to some embodiments of the current invention, to overcome this challenge and to maximize light absorption, we provide, and have successfully demonstrated, hybrid tandem cells which have a low index of refraction (<2.0) organic solar cell on top of the inorganic solar cell (with higher index of refraction >3.5). Organic materials have refractive indices of 1.7˜2.0. In such an arrangement, the reflection loss of inorganic solar cells can be reduced, and higher overall cell efficiency can be obtained by the tandem organic/inorganic PV cell.

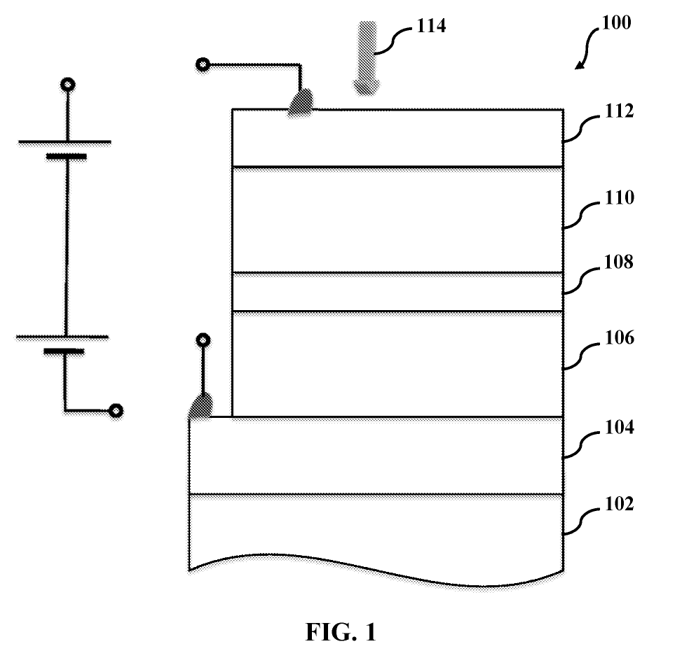

A tandem photovoltaic cell according to some embodiments of the current invention is shown in FIG. 1. The tandem photovoltaic cell 100 includes a substrate 102, a first electrode 104 formed on said substrate 102, and a first sub-cell 106 comprising a first light absorption material and formed on said first electrode 104. The tandem photovoltaic cell 100 also includes an inter-cell layer 108 formed on said first sub-cell 106, and a second sub-cell 110 comprising a second light absorption material and formed on said inter-cell layer 108. The tandem photovoltaic cell also includes a second electrode 112 formed on said second sub-cell 110. The second electrode 112 is at least partially transparent to light 114 of a spectral range that can be absorbed by said first and second absorption materials, said second electrode 112 being on a light reception side of said tandem photovoltaic cell 100. The inter-cell layer 108 provides electrical connection between said first and second sub-cells 106, 110 and is at least partially transparent to light of at least a portion of said spectral range. The second sub-cell 110 has a refractive index to light within said spectral range that is less than a refractive index of said first sub-cell 106 to light within said spectral range.

This can be thought of as an index matching method to enhance light transmittance at air/substrate interfaces, for example analogous to other optical applications such as lens anti-reflection coating techniques. In this example, we use polymer solar cells with multi-layer structures as the front sub-cell units.

The overall device specifications according to some embodiments are given below:

1. An electrical connection between the two sub-cells can be established by n- and p-type metal oxides or polyelectrolytes via thermal deposition or solution processes. Similarly, other types of tunnel junctions, as long as they satisfy the electrical and optical requirements, can be used for this type of cell.

2. In front of the top contact of inorganic photovoltaic films, medium refractive index materials can be used to reduce the reflectance at the interface, and allow more light to pass through the polymer sub-cells to the back inorganic sub-cells, resulting in more efficient light harvesting and higher conversion efficiency.

3. A transparent electrode can be coated on top of organic photoactive layer. Suitable materials can include one or more of ITO, a thin layer of Au, a metal oxide/metal/metal oxide composite electric contact, and a metallic nano-wire electrode (such as a Ag or Cu-NW composite electrode). In such cases, the reflective loss can be minimized, for example, less than 10%.

4. Organic photovoltaic units can also be conformed on a separated plastic substrate, and then laminated on top of inorganic sub-cells, for example, with electronic glue.

The resultant devices according to above mentioned embodiments can generate high efficiency without significantly complicated or costly processing. The concepts can also be applied to c-Si, p-Si, a-Si, CIGS, CZTS, and other types of inorganic solar cells, which typically have high reflection loss. The low refractive index solar cell can also comprise materials other than organics, such as hybrid solar cells or dye/perovskite sensitized solar cells. Therefore, embodiments can be generalized to other photovoltaic systems for high power conversion efficiency.

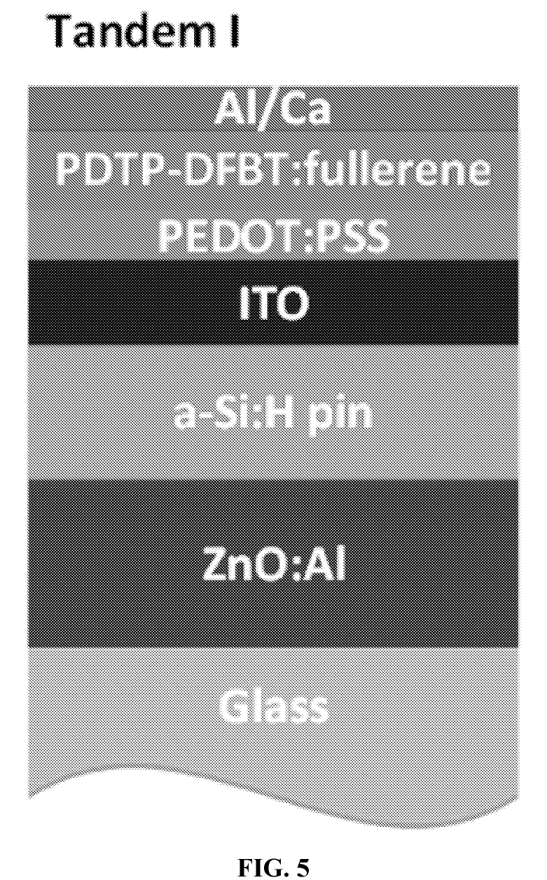

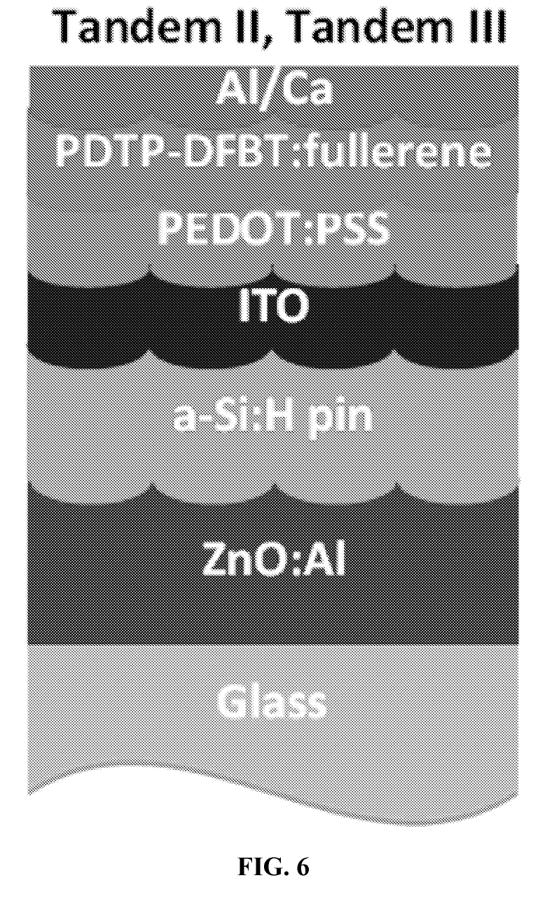

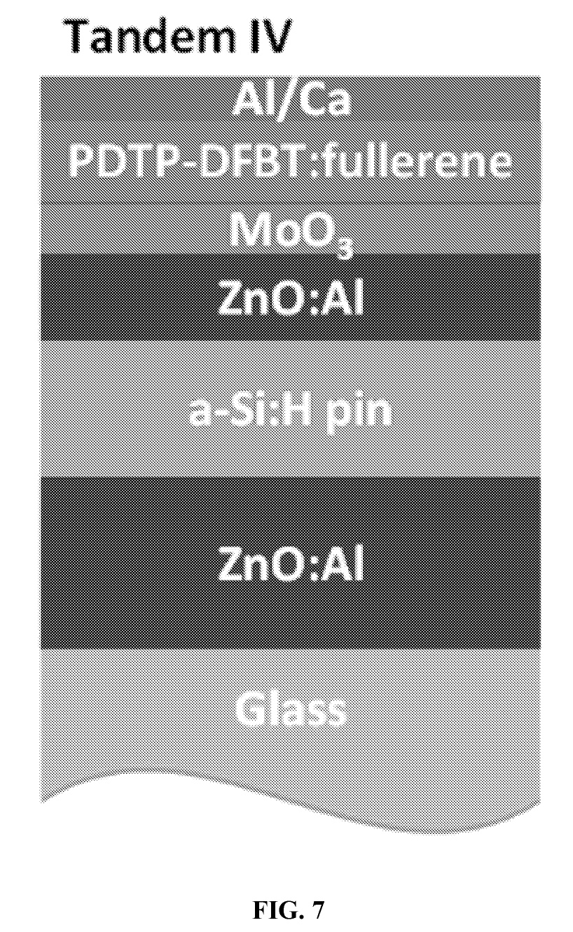

Some embodiments can have the following features, which are described in more detail below with respect to FIGS. 5-9:

1. A combined top-light-harvesting structure with a similar structure of Tandem I, in which the light comes in from the transparent top electrode, and the top sub-cell acts as an anti-reflection layer for the bottom cell, which features an advanced optical design;

2. Example p-type metal oxides for a Tandem IV structure: MoO₃, V2O5, WO3, NiO. Sub-oxides of metals, for example, Mo, V, W or Ni, may also be used;

3. A textured structure in Tandem II and III that has a triangle shape, with a tilt angle of ˜30 degree and base width of 1500 nm. In this case, we reached a compromise between the optical gain and the full coverage of the polymer film (in order to have a good diode). Increasing the tilt angle results in a strong leaking of the top polymer solar cells.

As used herein, the terms “about” and “approximately,” when referring to a measurable value such as an amount, a temporal duration, and the like, is meant to encompass variations of ±20% or ±10%, more preferably ±5%, even more preferably ±1%, and still more preferably ±0.1% from the specified value, as such variations are appropriate to perform the disclosed methods.

The following examples describe some embodiments in more detail. The broad concepts of the current invention are not intended to be limited to the particular examples. Further, concepts from each example are not limited to that example, but may be combined with other embodiments of the system.

### EXAMPLES

In order to maximize the efficiency of low efficiency solar cells, a solar cell made by stacking the multiple absorbers with complementary absorption spectra, a so called tandem cell, is considered as one of the most effective approaches. [3, 9-14] In this work, we have demonstrated that the combination of a-Si:H and polymer can be used to form a tandem cell whose efficiency is above 10%. We applied 200 nm-thick a-Si:H as a front cell and a 120 nm-thick PDTP-DFBT:fullerene bulk heterojunction as a back cell. The band gaps of a-Si:H and polymer absorbers are 1.8 eV [15] and 1.38 eV [16], respectively, and a conversion efficiency of a standalone single junction of both cells is 6˜7.5%. From this ultrathin polymer/a-Si:H tandem cell made on a flat surface substrate, a respectable conversion efficiency of 10.5% was obtained, which is an 84% improvement over the previous record for a hybrid polymer/a-Si tandem cell (5.7% reported for the best case). [16] We also demonstrated that some of the key elements for achieving such high efficiency tandem cells are i) the high quality fabrication of each cell component, ii) the engineering of the interface between a-Si:H and polymer, which dramatically promotes light harvesting, and iii) optical management in the multilayer structure for a photocurrent balance. Our result also promises potential efficiency of ˜13.5% when the cells are formed on a textured surface for enhancing light harvesting of both sub-cells.

Results

Single Junction Optimization.

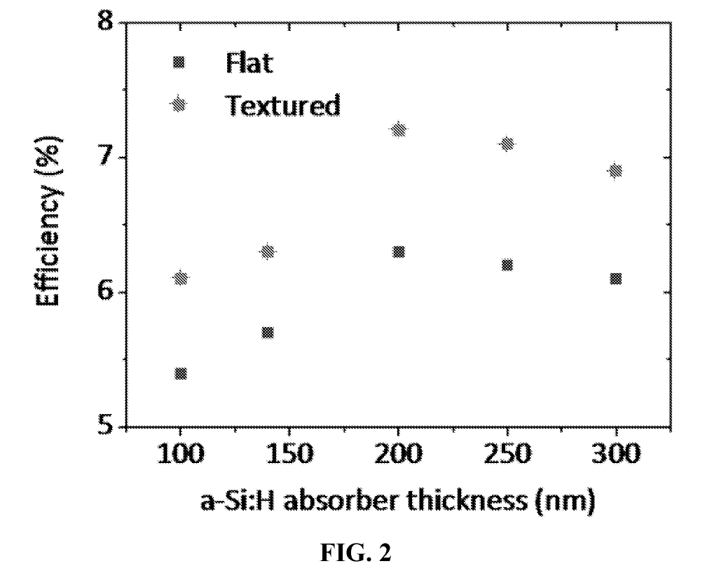

For the fabrication of a high performance polymer/a-Si:H tandem solar cell, we have optimized each single junction cell individually. For light trapping on the a-Si:H front cells, ZnO:Al films on the glass substrates were textured prior to a-Si:H deposition by dipping them into diluted HCl solution (DI water:HCl=100:1). FIG. 2 shows the performance of a-Si:H single junction on flat and textured ZnO:Al as a function of the absorber thickness. The maximum efficiency of a-Si:H single junction was achieved at the absorber thickness of 200 nm because photocurrent starts saturating and fill factor (FF) degradation occurs for the cell with an absorber thickness >200 nm. Therefore it can be expected that the best performance of the tandem device with a polymer cell is achievable if the photocurrent is controlled by the front cell at the absorber thickness of 200 nm. However, embodiments of the invention are not limited to 200 nm.

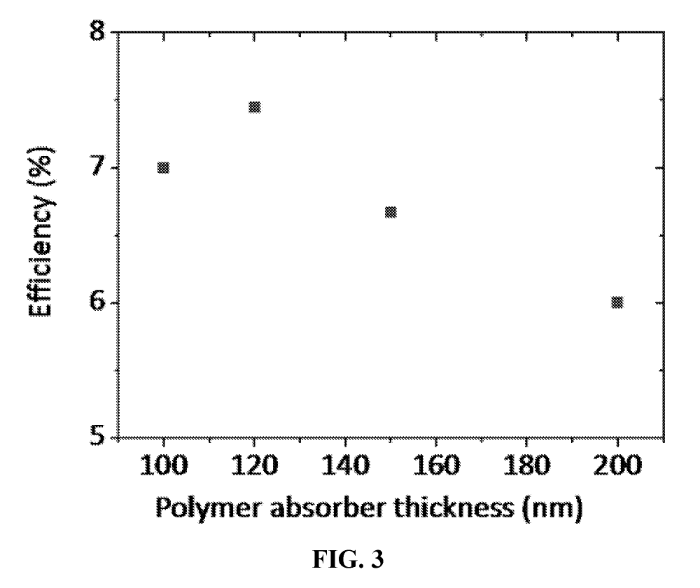

We customized a polymer back cell to ensure sufficient photocurrent generation so that the back cell does not limit the photocurrent in the tandem cell. First, we adjusted the ratio of PDTP-DFBT:fullerene blend film to obtain the highest photoresponse in the near IR range in external quantum efficiency (EQE) and to maximize FF. The most desirable performance was achieved at a polymer:fullerene ratio of 1:2. [11] Second, we optimized the thickness of polymer single junction cells since carrier mobility in organic photovoltaic materials is severely limited by the short conjugated length and large energetic disordering. [11] FIG. 3 shows the performance of the optimized polymer:fullerene single-junction solar cells as a function of the absorber thickness. The maximum efficiency was achieved at an absorber thickness of 120 nm. Further increasing the film thickness resulted in substantial FF degradation due to the strong field dependent charge recombination in the bulk film, [18] while reducing the film thickness resulted in severe decrease in short circuit current (Jsc) and slight gain in FF. Since Jsc is more important to match with that of the front cell, a 120 nm polymer:fullerene film was used to construct the tandem cells. However, embodiments of the invention are not limited to 120 nm. For example, according to some embodiments of the invention, the back cell has a thickness between approximately 80 nm and approximately 1000 nm.

Engineering of a-Si:H/Polymer Interfaces

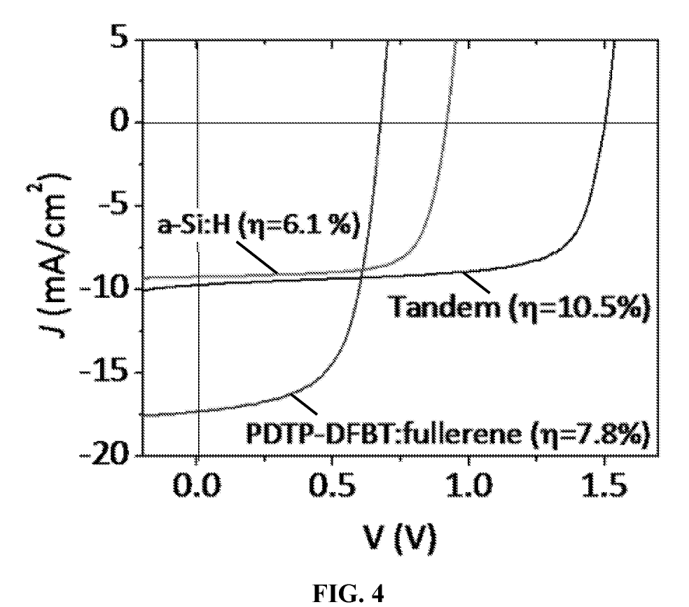

The photovoltaic parameters of reference flat 200-nm a-Si:H and 120-nm polymer single junction solar cells are summarized in Table 1. Current-voltage (J-V) curves are shown in FIG. 4. We have formed a series connection of these two optimized cells with minimized series resistance at the junction, which is essential to obtain the best performing tandem devices. [3, 9-14] Typically in thin film tandem cells, ultrathin doped layers are employed to form tunnel junctions between the sub-cells with extremely high doping. [2, 13, 14] Although ultrathin heavily n-doped a-Si:H film can be obtained, the hole collection layer (HCL) for polymer cells such as MoO3 and Poly(3,4-ethylenedioxythiophene) Polystyrene sulfonate (PEDOT:PSS) can be neither ultrathin nor highly doped. [19-21] Therefore, we applied ZnO:Al or indium-tin-oxide (ITO) as interfacial conducting layers (ICLs) between a-Si:H and polymer cells to promote electrical conduction. According to some embodiments, the inter-cell layer has a thickness of approximately 100nm to approximately 300 nm. According to some embodiments, the inter-cell layer comprises multiple layers. The inter-cell layer works as a cathode for the front sub-cell, and as an anode for the back one. ITO was paired with PEDOT:PSS, while ZnO:Al was employed for MoO3 since the strongly acidic PEDOT:PSS etches ZnO:Al during a deposition process. The transparent conducting oxide (TCO) middle layer easily connects the two sub-cells together in series without a tunneling junction. In addition, since the charge transport is along the vertical direction within the 100 nm-thick TCO, it causes negligible resistance.

TABLE 1

| | | Efficiency | V_{OC} | J_{SC} | FF |
|---|---|---|---|---|---|
| Cell | Interlayer | % | mV | mA/cm² | % |
| a-Si:H Single | N/A | 6.1 | 920 | 9.2 | 71.5 |
| junction | | (6.0) | (918) | (9.1) | (71.4) |
| Polymer single | N/A | 7.8 | 690 | 17.3 | 64.7 |
| junction | | (7.1) | (675) | (17.1) | (61.6) |
| Tandem I | ITO/ | 10.5 | 1544 | 9.8 | 69.2 |
| (Flat) | PEDOT:PSS | (10.2) | (1511) | (9.8) | (69.3) |
| Tandem II | ITO/ | 6.6 | 1559 | 11.5 | 36.8 |
| (Mildly Textured) | PEDOT:PSS | (6.5) | (1492) | (11.0) | (39.6) |
| Tandem III | ITO/ | 5.9 | 1510 | 12.5 | 31.3 |
| (Heavily | PEDOT:PSS | (5.6) | (1506) | (12.7) | (29.1) |
| Textured) | | | | | |
| Tandem IV | ZnO:Al/ | 7.9 | 1475 | 8.0 | 67.3 |
| (Flat) | MoO₃ | (7.4) | (1491) | (7.5) | (65.4) |

*Average values in parenthesis obtained from data of 8 individual devices

Fabrication of Tandem Cells

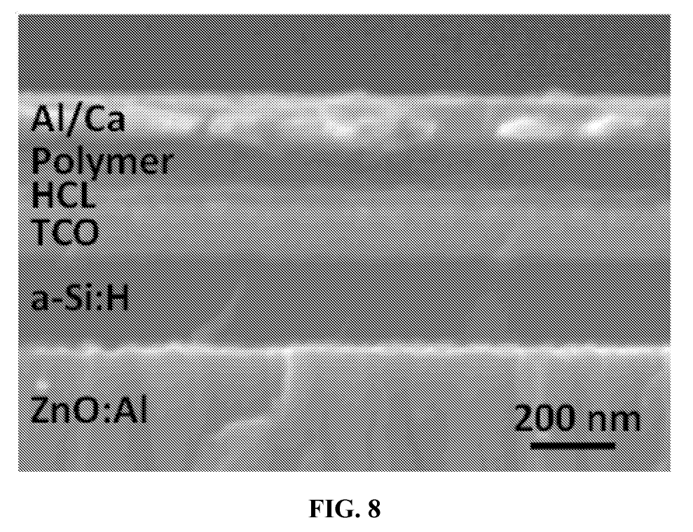

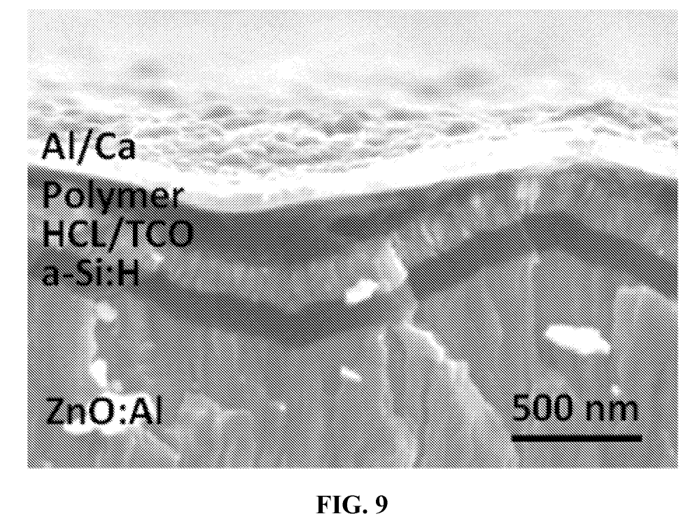

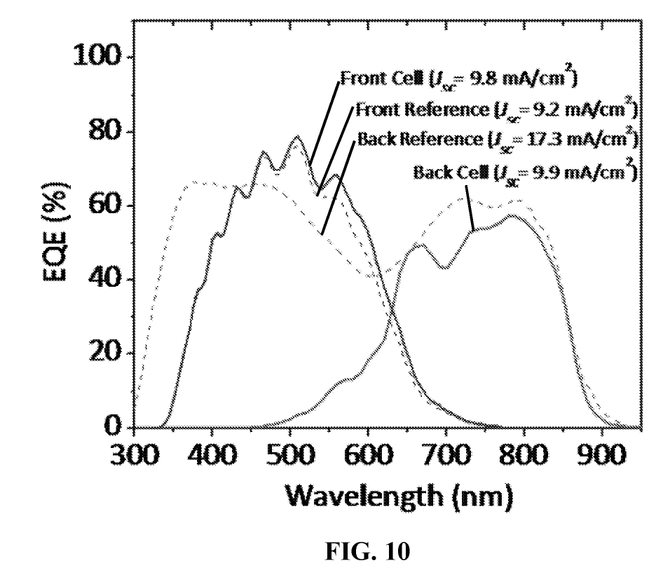

FIGS. 5-7 show schematics and FIGS. 8 and 9 show cross-sectional SEM images of tandem devices according to some embodiments of the invention. The photovoltaic performances of these tandem cells are summarized in Table 1. The performance of the cells varies significantly depending on the surface morphology, HCLs, and ICLs. The best performing device was obtained when the fully optimized single junction a-Si:H and polymer cells were deposited on a planar surface and connected through the following stacks: 40-nm PEDOT:PSS/100-nm ITO (marked as Tandem I in Table 2 and FIG. 5). An unprecedented level of efficiency, 10.5%, was demonstrated for Tandem I owing to the excellent open circuit voltage (VOC) of 1.54 V, which reaches 97% of the VOC of 1.61 V combined from the front and back cells, and due to maintained good FF of 70% implying that ICL offered an excellent series connection between front and back sub-cells (see Table 2 and FIG. 4). Calculated JSC by integrating EQE curves for the front and back cells are 9.2 and 9.6 mA/cm², respectively (see FIG. 10 and Table 2). Measured JSC of 9.2 mA/cm² by the J-V curve is identical to that of front cell implying reasonable current matching between the front and back cells with the photocurrent control by the front cell as aimed.

TABLE 2

| | | J_{SC} | J_{SC,a-Si:H} | J_{SC,a-Si:H} | J_{SC,polymer} | J_{SC,Polymer} |
|---|---|---|---|---|---|---|
| | | Tandem | Front | Reference | Back | Reference |
| Cell | Interlayer | (mA/cm²) | (mA/cm²) | (mA/cm²) | (mA/cm²) | (mA/cm²) |
| Tandem I | ITO/ | 9.8 | 9.8 | 9.2 | 9.9 | 17.3 |
| | PEDOT:PSS | | | | | |
| Tandem | ZnO:Al/ | 7.9 | 8.0 | 9.2 | 8.1 | 17.3 |
| IV | MoO3 | | | | | |

FIG. 8 shows a typical cross-sectional SEM image of a tandem cell made on a flat surface such as Tandem I and Tandem IV. FIG. 9 shows a typical cross-sectional SEM image of a tandem cell made on a textured surface such as Tandem II and III. In the flat tandem structure, the layer-by-layer structure can be clearly seen, while the thickness of polymer:fullerene film is not uniform in the textured tandem cell.

The obtained efficiency of 10.5% is respectable when considering the 10˜12% efficiency of thin film silicon tandem cells (a-Si:H/μc-Si:H micromorph) was obtained on highly textured ZnO:B/glass substrates by applying significantly thick μc-Si:H back cells (few microns). [3,13,14] Typically the surface texturing of thin film Si solar cells results in an efficiency boost up to 20%˜40% compared to the cells made on a flat surface. By depositing polymer/a-Si:H tandem cells on the heavily textured surface, in principle, a 13˜15% efficient polymer/a-Si:H tandem cell is achievable if no degradation occurs.

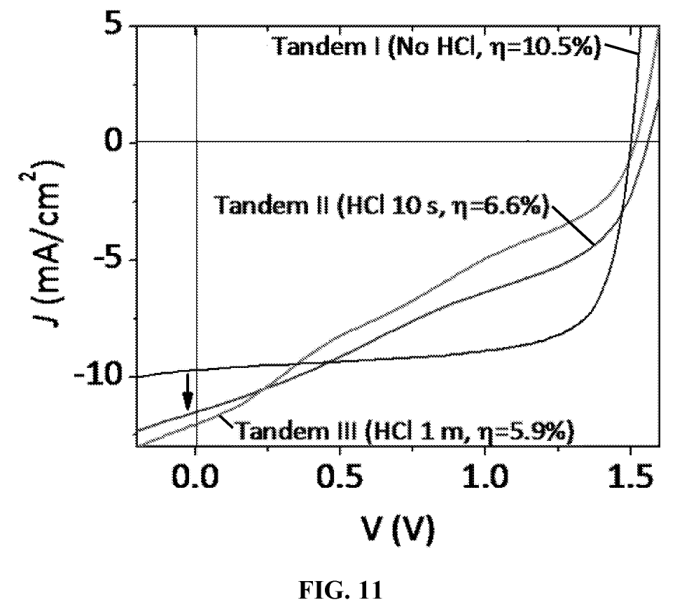

Therefore, we have fabricated our polymer/a-Si:H tandem cells on textured ZnO:Al/glass substrates. The ZnO:Al film on the glass substrate was textured by dipping into diluted HCl solution. FIG. 11 and Table I show the J-V curves and photovoltaic parameters of polymer/a-Si:H tandem cells on ZnO:Al films with different HCl treatment time, respectively (Tandem I, Tandem II, and Tandem III). The surface of the substrate, and therefore of at least some of the layers deposited there, was rough on a scale of wavelengths of light that can pass therethrough. The HCl concentration in the etching solution and the etching time are the major parameters controlling the roughness. The flat ZnO:Al layer becomes increasingly rough as the ZnO:Al is etched away over time. The properties of the rough surface are etching condition dependent. According to some embodiments, the rough surface can have substantially triangular structures that have bases that are approximately 1500 nm to within about 10% and have sides that make an angle of about 30 degrees (to within a few degrees) with the base.

As expected, increasing HCl treatment time resulted in substantial enhancement of JSC of the tandem cell with maintained high VOC. Textured Tandem II and III give higher photocurrent at short circuit point compared to Tandem I due to the light trapping effect. However, FF was substantially degraded due to a device shunt as seen in the J-V curves in FIG. 11. The degradation is more severe for the heavily textured tandem cell (Tandem III). On the one hand, as evidenced by a cross-sectional SEM image in FIG. 9, this device shunt of Tandem II and Tandem III could be attributed to non-conformal deposition of PDTP-DFBT:fullerene on the rough textured-surface resulting in the formation of a short path between the top contact and the HCL/TCO. On the other hand, the polymer:fullerene film has large thickness variation. In the valley area of the textured surface shown in FIG. 9, the polymer film thickness is much more than the optimal thickness of the bulk heterojunction. Even though the large thickness helps with light absorption, the serious recombination loss could be another factor that results in dramatic degradation of FF. Therefore, the overall efficiency of the textured device is not greater than that of the planar cell. However, considering high JSC and VOC product of Tandem II and Tandem III, tandem cell efficiency beyond the record efficiency of micromorphs (12%) [12] or pure polymer tandem cells (10.6%) [11] may be obtainable once the conformal deposition of low band gap polymer on the textured surface can be realized via the innovation of coating techniques.

Role of Interfacial Layers

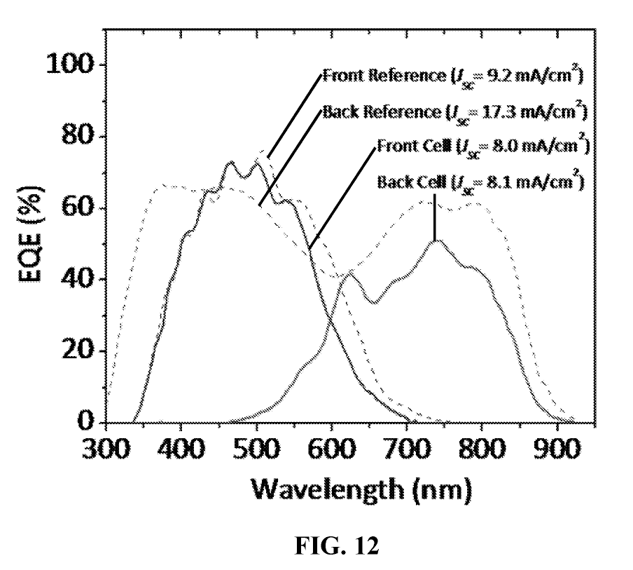

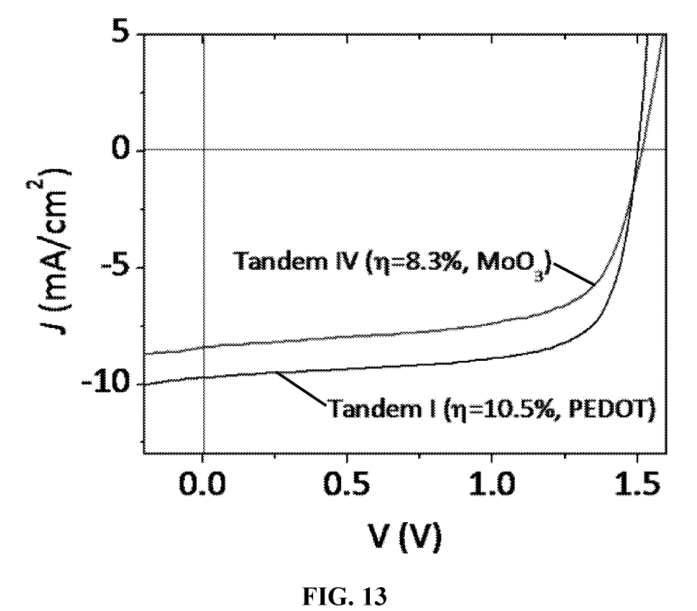

As mentioned earlier, an appropriate choice of ICL/HCL can facilitate the design of high efficiency a-Si:H/polymer tandem cells. As indicated in the Table 1 and FIGS. 10-13, there is a performance gap between the tandem cells fabricated with PEDOT/ITO interlayer (Tandem I) and MoO3/ZnO:Al interlayer (Tandem IV). For Tandem I with a PEDOT/ITO interlayer, the photocurrent recorded from the a-Si:H front cell is greater than that from the a-Si:H single-junction reference (see EQE in FIG. 10 and Table 2). Since we measured the photocurrent of an a-Si:H single-junction cell without applying any back-reflectors (=TCO/a-Si:H pin/TCO), photoresponse enhancement on a tandem cell in the photon range from 500 nm to 700 nm can be associated with enhanced back reflection from the PEDOT/ITO stack. For Tandem IV with a MoO3/ZnO:Al interlayer, on the other hand, the photoresponse from 500 nm to 700 nm was reduced compared to that of the a-Si:H single-junction reference (see EQE in FIG. 12 and Table 2). This resulted in reduced JSC of the entire tandem cell structure (see J-V curves in FIG. 13). Such parasitic absorption at the back of the a-Si:H front cell in Tandem IV is due to the high refractive index of MoO3, [21] whereas enhanced back-reflection at the front cell in Tandem I originates from the appropriate refractive index down-gradient from TCO to PEDOT:PSS to polymer photoactive layer. [22]

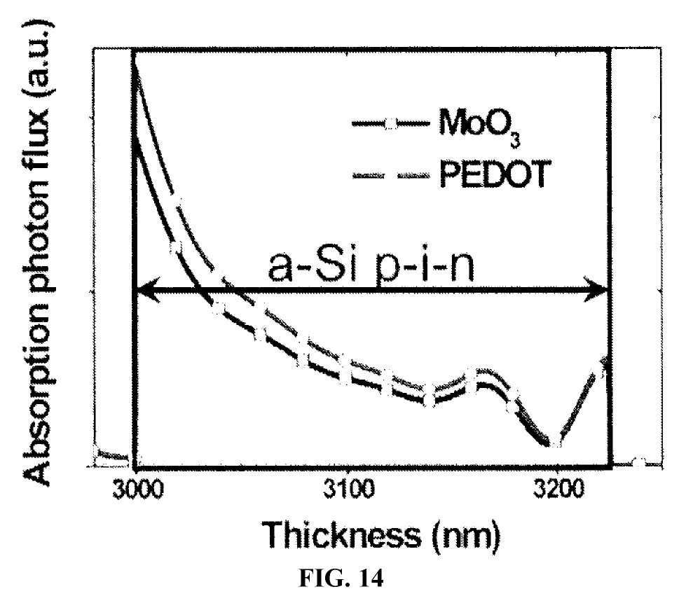

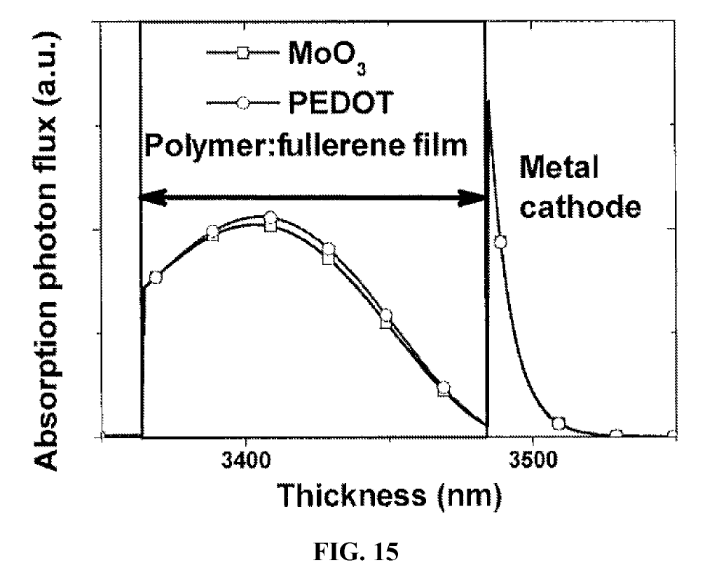

In planar tandem structure, we further carried out optical simulations using a transfer matrix method to determine how the ICL affects the absorption profile in multi-layer structure. [23] The absorbed photon flux distribution in the two sub-cells using MoO3 and PEDOT as interconnection layers is shown in FIGS. 14 and 15. It is clearly seen in FIG. 14 that using ITO/PEDOT as an ICL has resulted in approximately 15% higher absorption in the front a-Si sub-cell than in the AZO/MoO3 case, consistent with the Jsc enhancement shown in FIG. 14. The interconnection layers have less of an influence on the absorption in the back sub-cell, as shown in FIG. 15. The absorption profile versus film thickness is obtained based on the light distribution in the multilayer structure and the standard AM1.5G solar spectrum. Such observation shows that it is critically important to select interconnection layers with proper optical parameters, so as to maximize the light harvesting in photovoltaic cells, especially in the tandem structures. It is possible to further tune the optical field and absorption profile in the multilayer structure through changing the thickness of the ICL, i.e. MoO3 and PEDOT. However, the thickness has been determined based on the requirement for good electrical contact.

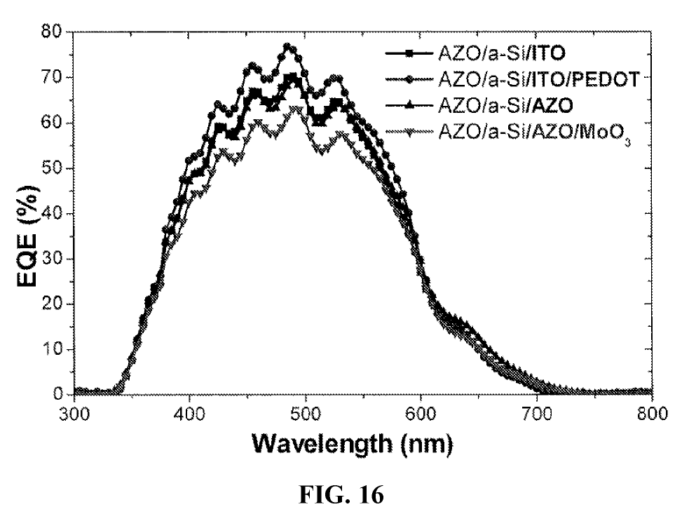

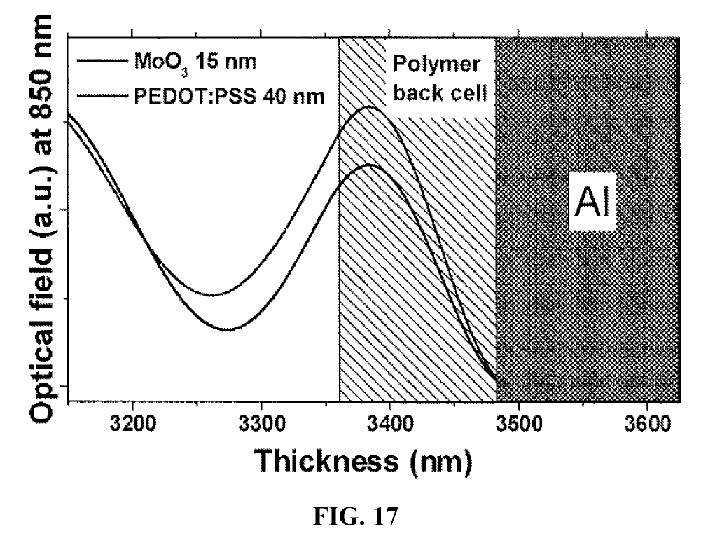

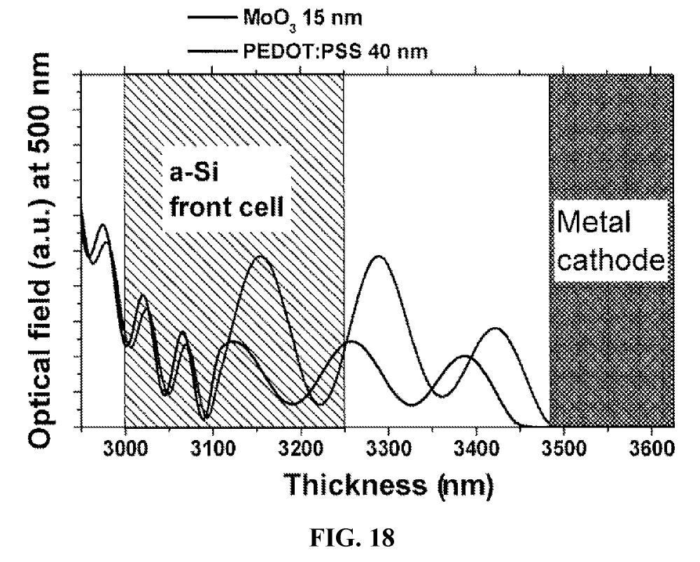

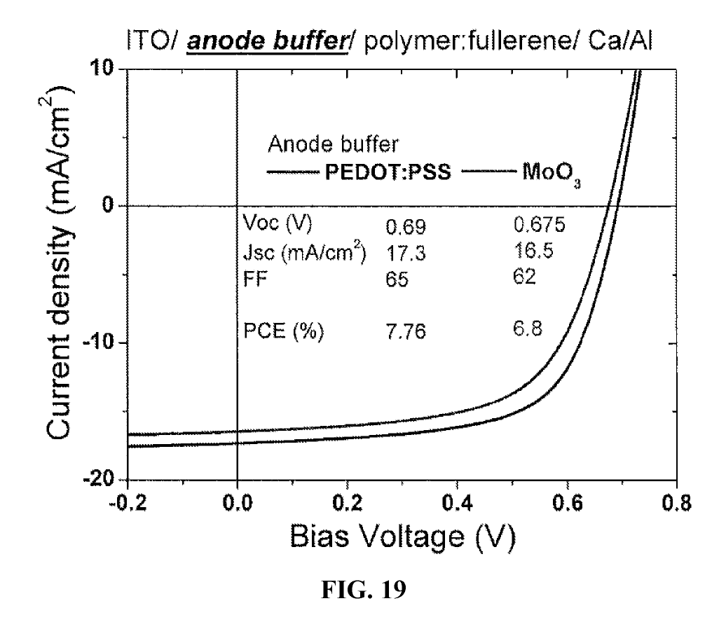

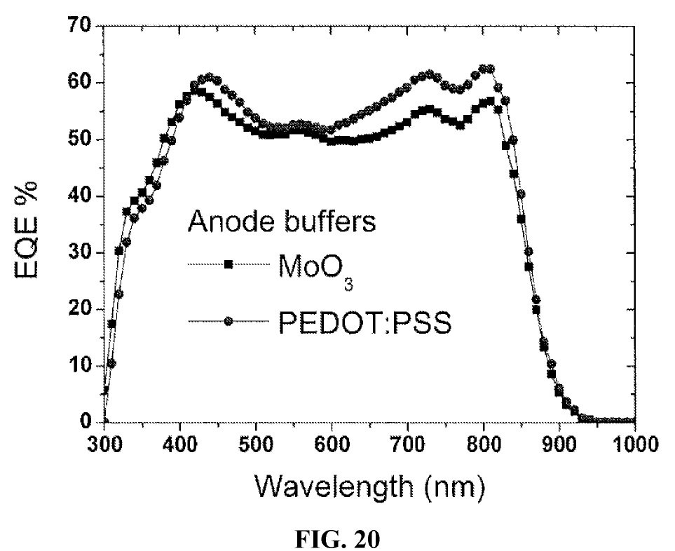

We argue that PEDOT has stronger reflectance than MoO3, benefiting the light absorption of the front cell. As shown in FIG. 16, simply stacking a layer of MoO3 or PEDOT can reduce or enhance the external quantum efficiency. The PEDOT layer can enhance the overall absorption of the front a-Si cell by almost 10%, most likely due to strong light reflectance at ITO/PEDOT interface, while MoO3 results in more optical loss, and thus lower absorption. As shown in FIGS. 17 and 18, compared with MoO3, the PEDOT layer reflects more visible light (500 nm) to pump the a-Si front sub-cell, while still allows more near IR light (850 nm) to penetrate into the polymer back sub-cell. That is why the photocurrent of the tandem cell can be dramatically enhanced. It should be noted here that MoO3 has a relatively large refraction index ˜2.5, which is larger than both AZO and polymer films. Also, the thickness according to some embodiments is only 15 nm, and the film might not be uniform enough to have high optical quality. Such a layer may lock more light within due to waveguide mode, especially when light scattering occurs in the real device situation, causing optical loss for both front and back sub-cells. On the other hand, MoO3 has been recognized as an exciton quencher and recombination site for the polymer:fullerene bulk heterojunction. [27] In our case, we tested the single junction polymer cell using PEDOT and MoO3 as anode buffers. As shown in FIG. 19, PEDOT based reference cell gives 7.76% efficiency, while using MoO3 causes decrease Voc Jsc and FF slightly. FIG. 20 gives EQE curves of the two single junction cells, and the integrated photocurrent values are consistent with the Jsc measured under AM1.5G. Thus, in addition to the optical loss, it could be another reason that damages the performance of the tandem cell.

Discussion

Our polymer/a-Si:H tandem cells address the following shortcomings from pure Si or organic-based tandem cells: i) extremely thick (2-3 μm) microcrystalline Si back cells required for the pure Si-based tandem cell were replaced by a 120 nm-thick low band gap polymer; [3,12,13] ii) most of the high band gap (Eg) polymer cells suffer from high Eg-to-qVoc deficit loss of ˜1.0 eV, [1,5-8] while it is only 0.85 eV for a-Si:H; [2,3,24,25] and iii) replacing a high band gap polymer cell in polymer tandem cells with thermal stable a-Si:H allows necessary thermal treatment required for connecting two polymer cells, since many efficient wide band gap polymer systems are not stable against thermal annealing over 120° C. [9]

In summary, we have demonstrated the highest efficiency inorganic/organic tandem cell that has been ever reported, with approximately 2× improvement over the previous record. The record efficiency of 10.5% was in part obtained due to the structural optimization of a-Si:H front/polymer back cells and the HCL/ICL between two sub-cells.

Methods

A 1.5 μm-thick ZnO:Al film was sputtered on a glass substrate as the bottom electrode. A a-Si:H front cell was first formed on ZnO:Al by depositing boron and carbon-doped p+ (window layer), undoped i (absorber), and phosphorus-doped n+ a-Si:H films at 250° C. in a plasma-enhanced chemical vapor deposition system with the following thicknesses: 10 nm-p, 200 nm-i, and 15 nm-n+ (see Reference 14 for details about a-Si:H cell fabrication). 100 nm-thick TCO, ITO or ZnO:Al, was deposited on a-Si:H p-i-n. MoO3 (15 nm) or PEDOT:PSS (40 nm) was deposited as an anode buffer for a subsequently deposited polymer back cell, serving as HCL for the back cell and as a charge recombination zone for electrons from the front cell and holes from back cell. [18-20] A 120-nm thick PDTP-DFBT:fullerene blend film was deposited on the HCLs via spin-coating (see Reference 10 for details about polymer cell fabrication). The tandem cell was completed by evaporating 20 nm Ca/150 nm Al with the definition of an active area of 2.5 mm². The values provided herein are purely exemplary, and the embodiments of the invention are not limited to these values.

The efficiency measurement was carried out under standard AM1.5G solar simulator illumination at the light intensity of 100 mW/cm². The light intensity is calibrated by a KG-5 Si photodiode which has been previously calibrated by NREL. Optical simulation based on the transfer matrix method was carried out using an in-house built software tool to calculate the optical field distribution, light absorption profile under AM1.5G solar light illumination. The optical parameters of glass, MoO3, and cathode metal were taken from an existing database, [26] and other materials including metal oxide conductors and photoactive layers were experimentally determined at IBM Watson lab and UCLA. The calculation is done based on the assumption of ideal thin film quality, and may cause some deviation from the real cases. It is worth noting that the film thicknesses in the tandem cells falls into the range of a few tens of nanometers to a few hundred. Thus, the simulation is informative, since the light absorption is far less complete upon single pass, as we see in the results.

### REFERENCES

[1] Brabec, C., Scherf, U., & Dyakonov, Y. Organic Photovoltaics: Materials, Device Physics, and Manufacturing Technologies, 2nd Edition (Wiley-VCH, 2014)

[2] Luque, A. & Hegedus, S. Handbook of Photovoltaic Science and Engineering (Wiley, West Sussex, England, 2003).

[3] Shah, A. Thin-film Silicon Solar Cells (EPFL press, Lausanne, Switzerland, 2010).

[4] Darling, S. B. and You, F. Q. RSC Advances, 3, 17633 (2013)

[5] Small, C. E. et al. High-efficiency inverted dithienogermole-thienopyrrolodione-based polymer solar cells. Nat. Photon. 6, 115-120 (2012).

[6] Chen, H. Y. et al. Polymer solar cells with enhanced open-circuit voltage and efficiency. Nat. Photon. 3, 649-653 (2009).

[7] Liang, Y. Y. et al. For the bright future—bulk heterojunction polymer solar cells with power conversion efficiency of 7.4%. Adv. Mater. 22, E135-E138 (2010).

[8] He, Z. et al. Enhanced power-conversion efficiency in polymer solar cells using an inverted device structure, Nature Photonics 6, 591-595 (2012)

[9] Kim, J. Y. et al. Efficient tandem polymer solar cells fabricated by all-solution processing. Science 317, 222-225 (2007).

[10] Dou, L. T. et al. Tandem polymer solar cells featuring a spectrally matched low bandgap polymer. Nat. Photon. 6, 180-185 (2012).

[11] J. B. You, et al, A polymer tandem solar cell with 10.6% power conversion efficiency, Nature Communication, 4, 1446-1455 (2013).

[12] Green, M., Emery, K., Hishikawa, Y., Warta, W., & Dunlop, E. D. Solar cell efficiency tables (version 43), Prog. Photovolt: Res. Appl. 22, 1-9 (2014).

[13] Meillaud, F. et al. Limiting factors in the fabrication of microcrystalline silicon solar cells and microcrystalline/amorphous (‘micromorph’) tandems, Phil. Mag. 89, 1-22 (2009)

[14] Biron, R. et al. New progress in the fabrication of n-i-p micromorph solar cells for opaque substrates. Sol. Energy Mater. Sol. Cells. 114, 147-155 (2013).

[15] Kim, J. et al., Efficiency enhancement of a-Si:H single junction solar cells by a-Ge:H incorporation at the pl a-SiC:H/transparent conducting oxide interface. Appl. Phys. Lett. 99, 062102 (2011)

[16] Dou, L. T., et al. Synthesis of 5H-Dithieno[3,2-b:2′,3′-d]pyran as an electron-rich building block for donor-acceptor type low-bandgap polymers, Macromolecules, 46, 3384-3390 (2013).

[17] Seo, J. H. et al, High Efficiency Inorganic/Organic Hybrid Tandem Solar Cells, Adv. Mat. 24, 4523-4527 (2012).

[18] Blom, P. W. M., Mihailetchi, V. D., Koster, L. J. A., & Markov, D. E. Device Physics of Polymer:Fullerene Bulk Heterojunction Solar Cells. Adv. Mater. 19, 1551-1566 (2007).

[19] Albrecht, S. et al., Efficient hybrid inorganic/organic tandem solar cells with tailored recombination contacts, Sol. Energy Mater. Sol. Cells, 127, 157-162 (2014).

[20] Shrotriya, V., Li, G., Yan, Y., Chu, C. W., & Yang, Y. Transition metal oxides as the buffer layer for polymer photovoltaic cells, Appl. Phys. Lett., 88, 073508 (2006).

[21] Brabec, C. J. et al. Origin of the Open Circuit Voltage of Plastic Solar Cells, Adv. Func. Mater., 11, 374-380 (2001).

[22] Deb, S. K. Physical properties of a transition metal oxide: optical and photoelectric properties of single crystal and thin film molybdenum trioxide. Proc. Roy. Soc. A 304 211-231 (1968).

[23] Peumans, P., Yakimov, A., Forrest, S. R. J. Appl. Phys. 93, 3693 (2003)

[24] Hoppe, H., Sariciftci, N. S., & Meissner, D. Optical constants of conjugated polymer/fullerene based bulk-heterojunction organic solar cells. Mol. Cryst. Liq. Cryst., 385, [233]/113-[239]/119 (2002).

[25] Faist, M. A. et al., Competition between the charge transfer state and the singlet states of donor or acceptor limiting the efficiency in polymer:fullerene solar cells, J. Am. Chem. Soc. 134, 685-692 (2012)

[26] Palik, E. D., ed. Handbook of Optical Constants of Solids (Elsevier Science, 1985).

[27] Subbiah, J., Amb, C. M., Irfan, I., Gao, Y., Reynolds, J. R., So, F. High-efficiency inverted polymer solar cells with double interlayer, ACS applied materials & interfaces 4, 866-870

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1. A tandem photovoltaic cell, comprising:
a substrate;
a first electrode formed on said substrate;
a first sub-cell comprising a first light absorption material and formed on said first electrode;
an inter-cell layer formed on said first sub-cell;
a second sub-cell comprising a second light absorption material and formed on said inter-cell layer; and
a second electrode formed on said second sub-cell,
wherein said second electrode is at least partially transparent to light of a spectral range that can be absorbed by said first and second absorption materials, said second electrode being on a light reception side of said tandem photovoltaic cell,
wherein said inter-cell layer provides electrical connection between said first and second sub-cells and is at least partially transparent to light of at least a portion of said spectral range, and
wherein said second sub-cell has a refractive index to light within said spectral range that is less than a refractive index of said first sub-cell to light within said spectral range.

2. A tandem photovoltaic cell according to claim 1, wherein said second sub-cell is an organic sub-cell and said first sub-cell is an inorganic sub-cell.

3. A tandem photovoltaic cell according to claim 1, wherein said second sub-cell is a multilayered sub-cell.

4. A tandem photovoltaic cell according to claim 1, wherein said first sub-cell has a refractive index to light within said spectral range that is greater than 3.5.

5. A tandem photovoltaic cell according to claim 1, wherein said first sub-cell has a thickness of approximately 200 nm.

6. A tandem photovoltaic cell according to claim 1, wherein said second sub-cell has a thickness between approximately 80 nm and approximately 1000 nm.

7. A tandem photovoltaic cell according to claim 1, wherein said second sub-cell has a thickness of approximately 120 nm.

8. A tandem photovoltaic cell according to claim 1, wherein said inter-cell layer has a thickness between approximately 100 nm and approximately 300 nm.

9. A tandem photovoltaic cell according to claim 1, wherein said inter-cell layer comprises PEDOT:PSS.

10. A tandem photovoltaic cell according to claim 9, wherein said inter-cell layer further comprises a layer of ITO formed on said first sub-cell, wherein a layer comprising said PEDOT-PSS is formed on said layer of ITO.

11. A tandem photovoltaic cell, comprising:
a substrate;
a first electrode formed on said substrate;
a first sub-cell comprising a first light absorption material and formed on said first electrode;
an inter-cell layer formed on said first sub-cell;
a second sub-cell comprising a second light absorption material and formed on said inter-cell layer; and
a second electrode formed on said second sub-cell,
wherein at least one of said first sub-cell, said second sub-cell, or said inter-cell layer has a surface that is rough on a scale of wavelengths of light that can pass therethrough.

12. A tandem photovoltaic cell according to claim 11, wherein said second sub-cell is an organic sub-cell and said first sub-cell is an inorganic sub-cell.

13. A tandem photovoltaic cell according to claim 11, wherein said surface that is rough comprises substantially triangular structures.

14. A tandem photovoltaic cell according to claim 13, wherein said substantially triangular structures have bases that are approximately 1500 nm to within about 10% and have sides that make an angle of about 30 degrees (to within a few degrees) with the base.

15. A tandem photovoltaic cell, comprising:
a substrate;
a first electrode formed on said substrate;
a first sub-cell comprising a first light absorption material and formed on said first electrode;
an inter-cell layer formed on said first sub-cell;
a second sub-cell comprising a second light absorption material and formed on said inter-cell layer; and
a second electrode formed on said second sub-cell,
wherein said inter-cell layer provides electrical connection between said first and second sub-cells and is at least partially transparent to light of at least a portion of said spectral range, and
wherein said inter-cell layer comprises a p-type metal oxide.

16. A tandem photovoltaic cell according to claim 15, wherein said second sub-cell is an organic sub-cell and said first sub-cell is an inorganic sub-cell.

17. A tandem photovoltaic cell according to claim 15, wherein said p-type metal comprises at least one of an oxide or sub-oxides of Mo, V, W, or Ni.

18. A tandem photovoltaic cell according to claim 15, wherein said inter-cell layer further comprises a layer of ZnO:Al formed on said first sub-cell, wherein a layer comprising said p-type metal oxide is formed on said layer of ZnO:Al.
